(19) United States
(12) Patent Application Publication
(10) Pub. No.: US 2024/0038797 A1
(43) Pub. Date: Feb. 1, 2024

(54) MULTISPECTRAL INFRARED PHOTODETECTOR

(71) Applicant: COMMISSARIAT A L'ENERGIE ATOMIQUE ET AUX ENERGIES ALTERNATIVES, Paris (FR)

(72) Inventor: Giacomo BADANO, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/258,164

(22) PCT Filed: Dec. 15, 2021
(86) PCT No.: PCT/FR2021/052347

§ 371 Date: Jun. 16, 2023

(30) Foreign Application Priority Data
Dec. 17, 2020 (FR) FR20 13324

(51) Int. Cl. H01L 27/146

(52) U.S. Cl. CPC H01L 27/1462; H01L 27/1465; H01L 27/14627; H01L 24/13

(57) ABSTRACT

A device for multi-spectral photo-detection in the infrared includes a photo-detection stage and a filtering stage superimposed on top of one another. The photo-detection stage includes a read circuit, an active layer incorporating a matrix of photodiodes, and a support substrate, superimposed together in that order. The filtering stage includes filtering areas of a first type, each formed of an interference filter capable of transmitting the wavelengths of a first spectral band and of blocking the wavelengths of a second spectral band, and filtering areas of a second type, capable of transmitting at least part of the wavelengths of the second spectral band. The device further includes an adhesive layer, located between the photo-detection stage and the filtering stage, on the support substrate side, and an anti-reflective coating, located between the adhesive layer and the support substrate.

### TECHNICAL FIELD

The invention relates to a device for multi-spectral photo-detection in the infrared, i.e. a photon detection device, sensitive in the infrared, and including at least two types of pixels which differ by their respective spectral sensitivity ranges. In use, such a device is coupled to a cooler, to lower its temperature to cryogenic temperatures.

### PRIOR ART

An infrared multi-spectral photo-detection device conventionally includes a matrix of photodiodes integrated in a semiconductor substrate, and spectral filters to filter the infrared light arriving on the photodiodes. The semiconductor substrate, referred to herein as the active layer, advantageously rests on a support substrate (growth substrate after thinning) which confers the desired mechanical rigidity on the set.

More particularly, the invention relates to a so-called “hybridised” photo-detection device, i.e. incorporating a read circuit of the photodiodes which is located under the photodiode matrix. The read circuit is electrically connected to each of the photodiodes of the photodiode matrix, generally by metal beads.

An objective of the present invention is to provide a device for multi-spectral photo-detection in the infrared, hybridised, and offering improved performances in terms of colour reconstruction, in comparison with the prior art.

### DISCLOSURE OF THE INVENTION

This objective is achieved with a device for implementing a multi-spectral photo-detection in the infrared, which includes a photo-detection stage and a filtering stage, superimposed on top of one another along an axis called optical axis, wherein:
the photo-detection stage includes a read circuit, an active layer made of a semiconductor material, incorporating a matrix of photodiodes, and a support substrate, superimposed in that order along the optical axis, and with the read circuit electrically connected to the photodiodes of the photodiode matrix;
the filtering stage comprises a matrix of filtering areas which consists of filtering areas of at least two types, among which filtering areas of a first type, each formed of an interference filter and each capable of transmitting the wavelengths of a first spectral band and of blocking the wavelengths of a second spectral band, and filtering areas of a second type, each capable of transmitting at least part of the wavelengths of the second spectral band.

The support substrate may correspond to the residual portion of a growth substrate of the active layer, after thinning.

An interference filter refers to a filter wherein the separation of the wavelengths is based on the transmission of light in a given wavelength range and the reflection of light in another wavelength range (in contrast with absorbent filters consisting for example of a coloured resin in the visible).

According to the invention, the photo-detection device further includes:
an adhesive layer, which extends between the photo-detection stage and the filtering stage, with, in the photo-detection stage, the support substrate located on the adhesive layer side; and
an anti-reflective coating, which extends between the adhesive layer and the support substrate, and which is configured to reduce inner reflections in the infrared.

The photo-detection stage, including the photodiode matrix and its read circuit, forms a hybridised component.

Advantageously, during manufacture, the active layer is formed over a growth substrate, then hybridised with the latter on the read circuit. Afterwards, the growth substrate is thinned, to form the support substrate. This method allows having a surface that is as planar as possible at the support substrate, on the side opposite to the active layer. However, the planarization cannot be perfect. Furthermore, in use, the hybridised component is brought to very low temperatures, which exacerbates the residual flatness defect (in particular because of the thermal expansion coefficient difference between the material of the read circuit and the material of the active layer).

In order to limit in particular the risks of damage of the photodiode matrix, the filtering stage is preferably made separately, then attached by bonding on the photo-detection stage. Hence, there is an adhesive layer between the filtering stage and the photo-detection stage, more particularly between the filtering stage and the support substrate. Advantageously, this adhesive layer has a variable thickness in the space, to compensate for the flatness defect of the support substrate.

In the photo-detection device, pixels are defined each including one single photodiode of the photodiode matrix. In order to reduce a crosstalk between the pixels of the photo-detection device, it is necessary to bring the filtering stage and the photodiode matrix as close as possible. It is also necessary to keep a certain thickness of support substrate, to guarantee good mechanical stability of the device according to the invention. Bringing the filtering stage and the photodiode matrix close to each other then implies an adhesive layer that is as thin as possible.

The Inventors have then made the following remark: when the adhesive layer is in direct physical contact with the support substrate, an interface between the adhesive layer and the support substrate forms a reflective surface at infrared wavelengths, in particular at wavelengths detected by the photodiode matrix. Furthermore, the filtering areas of the filtering area matrix are also capable of reflecting light inside the photo-detection device, in particular the filtering areas each formed by an interference filter. Thus, an optical cavity is formed, above the photo-detection stage, between the support substrate and the interference filters of the filtering area matrix. In each pixel of the photo-detection device, the optical cavity is excited locally, at the wavelengths transmitted by the interference filter belonging to said pixel (the filter is not perfect, and barely reflects at these wavelengths). In each pixel of the photo-detection device, the optical cavity is excited by light transmitted throughout the filtering area belonging to said pixel. The optical cavity is also excited by light blocked by the filtering area of a neighbouring pixel, and arriving in the considered pixel for example because of the diffraction phenomena. This light, blocked by the neighbouring pixel, is largely reflected by the interference filter forming the filtering area of the considered pixel.

Due to the flatness defect of the support substrate, the reflective surface, formed at the interface between the adhesive layer and the support substrate, has a non-planar topology, with recesses and/or bosses. Hence, the optical cavity has a variable thickness, which depends on the considered location in a plane parallel to the plane of the photodiode matrix (the thickness of the optical cavity being defined according to an axis orthogonal to the plane of the filtering areas matrix). Furthermore, in use, the photo-detection device is brought to very low temperatures, which exacerbates the variations in the thickness of the optical cavity, due to the thermal expansion coefficient difference between the material of the active layer and the material(s) of the filtering area matrix.

Yet, the thinner the adhesive layer, the more this cavity is sensitive to variations in its thickness. This greater sensitivity of the optical cavity to variations in its thickness results in greater disparities in the rate of light reaching the photodiodes, from one pixel to another, and therefore in a greater disparity of a quantum efficiency coefficient, from one pixel to another. Furthermore, the cavity thickness variation affects the quantum efficiency coefficients differently, depending on whether the considered pixel includes a filtering area of the first type or a filtering area of the second type (in particular because a thermal expansion coefficient of the filtering area depends on the type of said filtering area).

In order to guarantee a good reconstruction of the colours, a person skilled in the art seeks to make a device that has both a low crosstalk (between the pixels including a filtering area of the first type and the pixels including a filtering area of the second type), and a high homogeneity of a quantum efficiency coefficient (over all of the pixels of said device). At first glance, these two requirements seem to be contradictory since a low crosstalk is obtained by the thinnest possible adhesive layer, and a high homogeneity of the quantum efficiency coefficient is obtained by a thick adhesive layer (to limit the sensitivity of the optical cavity to variations in its thickness). Once this problem is posed, the obvious solution would have been to find a trade-off on the average thickness of the adhesive layer.

In this case, the Inventors have had the idea of finding a solution to this problem using an anti-reflective coating, between the adhesive layer and the support substrate, configured to limit parasitic reflections in the infrared which would be formed otherwise at the interface between the adhesive layer and the support substrate. Thus, it is possible to obtain a photo-detection device which has both a low crosstalk (between the pixels including a filtering area of the first type and the pixels including a filtering area of the second type, in particular), thanks to a reduced thickness of the adhesive layer, and a substantially homogeneous quantum efficiency from one pixel to another. Thus, a colour reconstruction is improved, in comparison with the prior art.

The anti-reflective coating, disposed between the support substrate and the adhesive layer, in direct physical contact with the adhesive layer, has in this configuration a reflection rate which is preferably strictly lower than 1%, and even strictly lower than 0.5% or lower than 0.1%, at the wavelengths detected by the photodiodes of the wavelength matrix and transmitted by at least one of the filtering areas. The characteristics of the anti-reflective coating are adapted to obtain such a reflection rate, taking into account the refractive index of the adhesive layer at the considered wavelengths (for example between 1.5 and 1.6 at the considered wavelengths). Such a reflection rate is obtained, for example by optimising a thickness of the anti-reflective coating. For example, the anti-reflective coating consists of a layer of ZnS, with a thickness adapted to have such a reflection rate when it is covered by the adhesive layer.

The device according to the invention combines the advantages hereinbelow:
robustness and compactness, thanks to the constituent elements which are held together;
a filtering stage with no flatness defect, despite the hybridisation of a read circuit under the active layer; and
low crosstalk and high homogeneity of quantum efficiency.

Preferably, a surface topology of the support substrate has a peak-valley amplitude greater than or equal to 3 μm at 300 K, on the adhesive layer side, and a surface topology of the filtering stage has a surface topology with a peak-valley amplitude less than or equal to 300 nm at 300 K, on the adhesive layer side, a difference between these two surface topologies being compensated by variations in the thickness of the adhesive layer.

The device according to the invention may further include a matrix of microlenses, which extends between the adhesive layer and the filtering stage.

In at least one direction of the space, a distribution step of the microlenses of the microlens matrix may be a multiple of a distribution step of the photodiodes of the photodiode matrix.

Preferably, the device according to the invention further includes metal walls, which extend into the filtering layer, between neighbouring filtering areas.

The metal walls may extend together according to a grid, with at least one filtering area of the filtering area matrix in each opening of the grid.

Advantageously, each opening of the gate includes one single filtering area of the filtering area matrix.

Preferably, at least one portion of at least one of the metal walls is bordered by two intermediate partitions made of a dielectric material.

Advantageously, a thickness of the intermediate partitions, defined in a plane orthogonal to the optical axis, is comprised between 500 nm and 50 nm.

Preferably, each filtering area of the first type consists of a stack of layers each made of a dielectric material.

Each filtering area of the second type may be capable of transmitting the wavelengths of the second spectral band and the wavelengths of the first spectral band, and consisting of a dielectric material called filler material.

Alternatively, each filtering area of the second type may be capable of transmitting the wavelengths of the second spectral band and of blocking the wavelengths of the second spectral band, and consists of a respective interference filter.

The active layer may be made of an alloy of cadmium, mercury and tellurium.

The invention also relates to a system including a device according to the invention, and a cryogenic cooler thermally coupled to the device according to the invention, and capable of cooling said device down to temperatures lower than or equal to 200 K.

### BRIEF DESCRIPTION OF THE DRAWINGS

The present invention will be better understood upon reading the description of some embodiments given merely for indicative and non-limiting purposes, with reference to the appended drawings wherein:

FIG. 1 illustrates, according a sectional view in a vertical plane, a photo-detection device according to a first embodiment of the invention;

FIG. 2 illustrates, according a sectional view in a vertical plane, a photo-detection device according to a second embodiment of the invention;

FIG. 3A and FIG. 3B illustrate a photo-detection device according to a third embodiment of the invention, respectively according a sectional view in a vertical plane and according a sectional view in a horizontal plane;

FIG. 4A and FIG. 4B illustrate a photo-detection device according to a fourth embodiment of the invention, respectively according a sectional view in a vertical plane and according a sectional view in a horizontal plane;

FIG. 5 illustrates, according a sectional view in a vertical plane, a photo-detection device according to a fifth embodiment of the invention; and

FIG. 6 illustrates, according a sectional view in a horizontal plane, a photo-detection device according to a sixth embodiment of the invention.

### DETAILED DISCLOSURE OF PARTICULAR EMBODIMENTS

To facilitate reading, the axes of an orthonormal reference frame (Oxyz) have been represented in the figures. The axis (Oz) defines a vertical axis, whereas the plane (Oxy) defines a horizontal plane.

Throughout the text, the term “infrared” refers to a portion of the light spectrum belonging to a spectral band ranging from 0.78 μm to 50 μm, more preferably from 3 μm to 8 μm (mid-infrared, or LWIR) and/or from 8 μm to 15 μm (far-infrared, or LWIR).

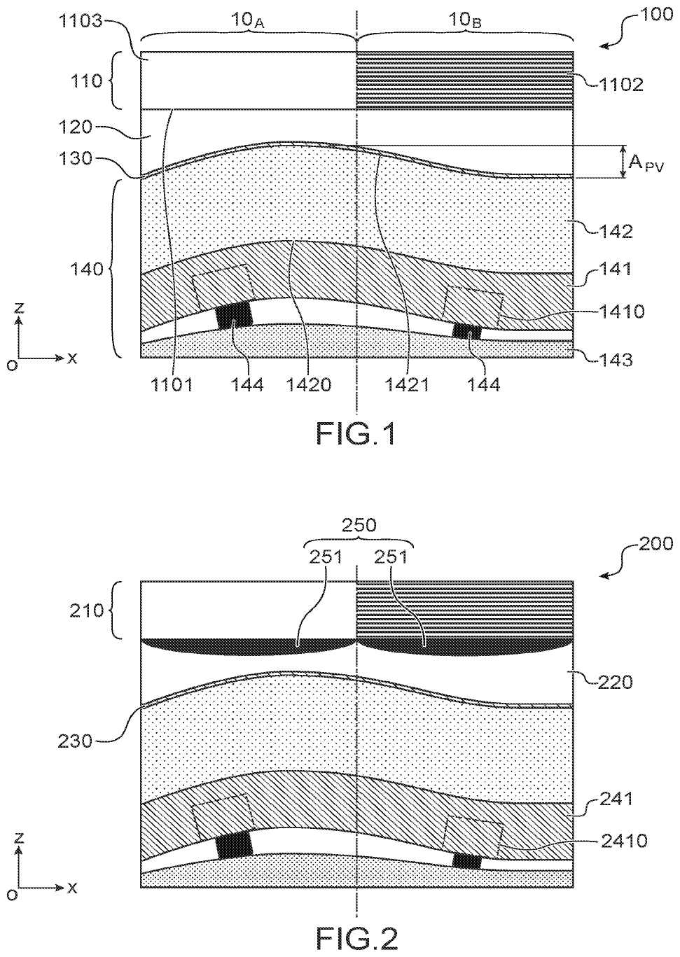

FIG. 1 schematically illustrates, according to a sectional view in a vertical plane (Oxz), a photo-detection device 100 according to a first embodiment of the invention.

In use, the photo-detection device 100 is coupled to a cooler of the cryogenic cooler type, to lower its temperature to ultra-low temperatures, called cryogenic temperatures, in particular temperatures lower than or equal to 200 K, and even lower than or equal to 150 K, or lower than or equal to 120 K.

The photo-detection device 100 includes, superimposed in that order along the axis (Oz): a filtering stage 110, an adhesive layer 120, an anti-reflective coating 130, and a photo-detection stage 140.

The photo-detection stage 140 includes a semiconductor substrate 141, called active layer, a support substrate 142, and a read circuit 143, superimposed together along the optical axis (Oz) with the active layer 141 between the support substrate 142 and the read circuit 143.

A matrix of photodiodes is integrated in the active layer 141. The photodiodes 1401 of said matrix are schematically represented by dotted lines. The photodiodes 1410 are distributed in space in a matrix arrangement, for example in rows and columns. Each photodiode 1410 herein defines a respective pixel of the photodiode matrix, as well as a respective pixel 10_{A} or 10_{B} of the photo-detection device 100. In particular, each pixel of the photo-detection device 100 is delimited by vertical surfaces extending over the entire height of the device 100, and incorporates one single photodiode 1410. In FIG. 1, the boundary between the pixels 10_{A} and 10_{B} has been identified by a dot-dash line.

The active layer 141 herein consists of an alloy of cadmium, mercury and tellurium (HgCdTe). The invention is not limited to this material, the active layer 141 may also consist of a semiconductor alloy made of a III-V material such as gallium arsenide, indium arsenide, gallium nitride, gallium antimonide, or a ternary alloy such as InxGa1-xAs, etc. A III-V material refers to a material composed of one or more element(s) from the column III of Mendeleev periodic table (for example boron, gallium, aluminium, indium, etc.) and from the column V of the same table (for example arsenic, antimony, phosphorus, etc.).

The support substrate 142 may correspond to the residual portion of a growth substrate of the active layer 141, after thinning of the latter. The support substrate 142 allows conferring a sufficient mechanical rigidity on the device 100, in particular in use at low temperature. Preferably, the thickness of the support substrate 142, measured according to the axis (Oz), is larger than or equal to 10 μm, comprised for example between 10 μm and 20 μm. With an active layer 141 made of HgCdTe, the support substrate 142 is advantageously made of an alloy of zinc, mercury and tellurium (HgZnTe).

The read circuit 143 is configured to receive photo-currents generated at the photodiodes 142, and convert them into current-type physical quantities such as an electrical current, an electrical voltage, or an electrical charge, compatible with signal processing chains. The read circuit 143 is electrically connected to the photodiodes 1410, herein by a series of indium balls 144 each extending between one photodiode 1410 of the active layer 141 and the read circuit 143.

Thus, the photo-detection stage 140 forms a so-called “hybridised” component, incorporating both a detection circuit (the active layer 141 including the photodiodes) and a read circuit of the photodiodes (the read circuit 143).

In practice, the active layer 141 has a certain flatness defect. Instead of extending in planes parallel to the plane (Oxy), the larger faces of the active layer 141 actually have a non-planar shape with at least one recess and/or at least one boss. In use, the photo-detection device 100 is brought to a very low temperature, which exacerbates the flatness defect, because of the thermal expansion coefficient difference between the material of the read circuit 143 and the material of the active layer 141.

During manufacture, the active layer 141 is formed over a growth substrate, then hybridised with the read substrate, then the growth substrate is thinned in order to obtain the support substrate 142. The support substrate 142 extends adjacent to active layer 141, and has a substantially constant thickness. The thinning achieves some planarization of the photo-detection device 100. However, this planarization is only partial, so that the flatness defect of the active layer 141 is found at least in part at the support substrate 142. In particular, the upper face 1421 of the support substrate 142, located on the side opposite to the active layer 141, has a surface topology with at least one recess and/or at least one boss. For example, a surface topology of the upper face 1421 of the support substrate 142 has a peak-valley amplitude Apv greater than or equal to 3 μm at 300 K, comprised for example between 4 μm and 5 μm at 300 K. This peak-valley amplitude Apv is generally reached over a distance of at least twenty pixels from the device 100. This amplitude is increased when the device 100 is brought to cryogenic temperatures, in use.

The adhesive layer 120 extends above the upper face 1421 of the support substrate 142. The adhesive layer 120 allows securing the filtering stage 110 on the photo-detection stage 140, and extends more particularly between the filtering stage 110 and the support substrate 142. Preferably, it consists of a polymer adhesive.

On the support substrate 142 side, the adhesive layer 120 conforms to the shape of the upper face 1421 of the support substrate 142, which has a large peak-valley amplitude. On the filtering stage 110 side, the adhesive layer 120 conforms to the shape of a lower face 1101 of the filtering stage 110, which on the contrary has a substantially planar topology, close to a plane parallel to the plane (Oxy). For example, a surface topology of the lower face 1101 of the filtering stage 110 has a peak-valley amplitude less than or equal to 300 nm at 300 K, and even less than or equal to 100 nm or even less than or equal to 50 nm at 300 K. Hence, the flatness defect caused by the hybridisation, and exacerbated by the cold setting, is compensated by variations in the thickness of the adhesive layer 120. Hence, the adhesive layer 120 enables the filtering stage 110 to have a substantially planar topology, despite the flatness defect of the photo-detection stage 140 located hereinbelow. Advantageously, the average thickness of the adhesive layer is the smallest thickness of adhesive allowing for a compensation of at least 90% of the flatness defect, in peak-valley amplitude value. This allows bringing the filtering stage 110 and the photodiode matrix 1410 as close as possible, and thus limiting the crosstalk in the device 100. Crosstalk refers to the detection of a signal, by a photodiode of a pixel, generated by light incident on a neighbouring pixel. Another way to bring the filtering stage 110 close to the photodiode matrix 1410 may consist in reducing the thickness of the support substrate 142. However, this solution is limited by the fact that the mechanical stability of the device 100, in particular during thermal cycles of cooling and return to room temperature, is provided by the support substrate 142. Hence, the latter should have a substantially large thickness.

The filtering stage 110 herein consists of a matrix of filtering areas. The filtering area matrix includes at least two distinct types of filtering areas, which differ in particular by their respective transmission spectral band. In this case, the filtering area matrix includes a first type of filtering area 1102, and a second type of filtering area 1103. In this case, the neighbouring filtering areas are arranged directly adjacent in pairs, in physical contact over the entire surface of their respective faces located opposite one another. Each pixel of the device 100 herein includes one single filtering area of the filtering stage 110. Hence, each filtering area surmounts one single photodiode 1410.

Each filtering area 1102 of the first type is formed by a respective interference filter, capable of transmitting the wavelengths of a first spectral band in the infrared and of blocking the wavelengths of a second spectral band in the infrared. By transmitting, it should be understood letting pass with a transmission coefficient higher than or equal to 80%, or higher than or equal to 90% and even higher than or equal to 98%. By blocking, it should be understood preventing the passage with a transmission coefficient lower than or equal to 5%, or lower than or equal to 1% and even strictly lower than 0.1%. Each of the first spectral band and the second spectral band covers a portion of a spectral sensitivity band of the photodiode matrix integrated in the active layer 141. Advantageously, the first spectral band and the second spectral band together cover the entirety of said spectral sensitivity band. For example, each filtering area 1102 of the first type is a band-pass, or high-pass, or low-pass filter. In this case, each filtering area 1102 of the first type is for example a band-pass filter, capable of transmitting only the wavelengths of the first spectral band in the infrared. For example, the width of the first spectral band is comprised between 300 nm and 800 nm. For example, the first spectral band extends from 3.40 μm to 3.95 μm, or from 4.60 μm to 5.05 μm. Each filtering area of the first type herein consists of a stack of layers made of a dielectric material, for example Si and SiO₂ layers or Si and SiN layers.

Each filtering area 1103 of the second type is capable of transmitting at least part of the wavelengths blocked by a filtering area of the second type. In this case, each filtering area 1103 of the second type consists of a mere filler material, dielectric, which transmits both the wavelengths of the first spectral band and the wavelengths of the second spectral band. Preferably, each filtering area 1103 of the second type thus forms a transparent area, which transmits all the wavelengths of the spectral sensitivity band of the photodiode matrix integrated in the active layer. Thus, each filtering area 1103 of the second type, consisting of a mere filler material, has a homogeneous chemical composition over its entire volume. Preferably, the filler material has a refractive index less than 2.5. For example, it consists of silicon nitride. The height of a filtering area 1103, according to the axis (Oz), is equal to the height of a filtering area 1102, according to the same axis.

The photodiodes 1410 are sensitive to the wavelengths of at least one portion of each of the first and second spectral bands. Thus, the device 100 forms a device for implementing a photon detection, in the infrared. It is capable of discriminating the photons of at least two distinct spectral bands (multispectral detection, herein bispectral).

In the filtering stage 110, each filtering area is advantageously surrounded, on its four sides (except in the particular case of a filtering area located at the boundary of the matrix), by filtering areas of a type different from its own type. Thus, this ensures an optimum meshing of the detected different spectral bands, over the detection surface of the device 100.

In the device 100, the distribution step of the pixels 10A, 10B is preferably strictly greater than a maximum value of wavelengths transmitted by either one of the filtering areas and detected by the photodiodes. In this case, this distribution step is for example comprised between 8 μm and 15 μm.

According to the invention, an anti-reflective coating 130 extends between the upper face 1421 of the support substrate 142 and the lower face of the adhesive layer 120, in direct physical contact with the latter over their entire respective extents. The anti-reflective coating 130 has a reduced thickness, constant according to the axis (Oz). Thus, the surface topology of the upper face 1421 of the support substrate 142 is identical to the surface topology of the lower face of the adhesive layer 120. The anti-reflective coating 130 is configured to limit inner reflections in the device 100, which would otherwise exist at the interface between the adhesive layer 120 and the support substrate 142. It has an anti-reflective nature over a wide spectral band, which includes all wavelengths capable of being transmitted by the filtering stage and detected by the photo-detection stage. Its anti-reflective nature is defined by a very low reflection rate on said spectral band. This transmission rate is defined in association with the arrangement of the anti-reflective coating 130 under the adhesive layer 120, in direct physical contact with the latter. In this case, the anti-reflective coating 130 has a reflection coefficient strictly lower than 1% at the wavelengths capable of being transmitted by the filtering stage and detected by the photo-detection stage, when it is covered by the adhesive layer 120 and in direct physical contact with it. The anti-reflective coating may be monolayer, or bilayer, or multilayer with at least three layers. It consists of one or more material(s) with an intermediate refractive index between that one of the adhesive layer 120 and that one of the support substrate 141. Preferably, it comprises a layer made of ZnS or ZnSe. In this case, the anti-reflective coating consists of a single layer made of ZnS or ZnSe. Its thickness is optimised, through software optimisation, and takes into account the refractive index of the adhesive layer 120, possibly the refractive index of the support substrate 142, and the central wavelength of a useful spectral range (including all wavelengths capable of being transmitted by the filtering stage and detected by the photo-detection stage). In this case, the central wavelength is about 4 μm.

In use, the infrared light arrives at the photo-detection device 100 at the filtering stage 110, on the side opposite to the photo-detection stage 140, and oriented according to a beam substantially parallel to the axis (Oz). An optical axis of the device 100 extends parallel to the axis (Oz), and orthogonal to the plane (Oxy) of the filtering stage. In each pixel of the device 100, infrared light passes through a filtering area of the filtering stage, then passes through the support substrate 142, then reaches the active layer 141 where said light is detected by the photodiode 1410 of said pixels. The presence of the anti-reflective coating 130 allows limiting the apparition of inner reflections in the device 100, in particular reflections generated otherwise at the interface between the adhesive layer 120 and the support substrate 142.

Indeed, in the absence of the anti-reflective coating 130, parasitic reflections form at the interface between the adhesive layer 120 and the support substrate 142. These parasitic reflections are confined, in an optical cavity delimited in particular by the interface between the adhesive layer 120 and the support substrate 142. Due to the flatness defect of the support substrate 142, this optical cavity has a variable thickness, dependent on the considered location in a plane (Oxy). An infrared light rate, originating from an external scene to be imaged and arriving into the photo-detection stage 140 to be detected therein by the photodiodes, depends on the local thickness of the optical cavity, at the considered location in a plane (Oxy). Hence, this infrared light rate is variable, and depends on the considered location in a plane (Oxy). When the thickness of the adhesive layer 120 tends towards the coherence length of the infrared light originating from the external scene to be imaged and arriving into the photo-detection stage 140, this infrared light rate barely varies. This coherence length is typically in the range of 30 to 40 μm. However, in this case, the average thickness of the adhesive layer 120 is much smaller than these values, in order to reduce the crosstalk. Consequently, this infrared light rate varies considerably, in the absence of the anti-reflective coating 130. This results in large variations in quantum efficiency, from one pixel to another of the device 100.

Furthermore, when the device 100 is brought to cryogenic temperatures, the variations in the thickness of the optical cavity mentioned hereinabove are exacerbated by the difference in thermal expansion coefficient between the material of the active layer 141 and the filtering stage 110. Furthermore, the thickness of the optical cavity may be affected differently, depending on whether it extends at a filtering area of the first type or of the second type (a filtering area of the first type and an area of the second type, each possibly having distinct thermal expansion coefficients). This results in an increase in quantum efficiency variations, from one pixel to another of the device 100.

Thanks to the anti-reflective coating 130, these quantum efficiency variations are limited, while guaranteeing a reduced crosstalk thanks to the proximity between the filtering stage 110 and the photodiode matrix. This ultimately allows for a better reconstruction of the colours on an image formed using the device 100.

FIG. 2 schematically illustrates, according to a sectional view in a vertical plane (Oxz), a photo-detection device 200 according to a second embodiment of the invention. This second embodiment differs from the embodiment of FIG. 1 only in that it further includes a matrix 250 of microlenses 251, which extends between the filtering stage 210 and the adhesive layer 220. In this case, each of the microlenses 251 extends in direct physical contact with the filtering stage 210 and with the adhesive layer 220. The microlenses 251 are herein delimited by a planar face, adjacent to the filtering stage 210, and a convex cambered face, adjacent to the adhesive layer 220. The upper face of the adhesive layer 220, on the side opposite to the support substrate, herein follows the topology of the microlens matrix 250.

In this case, each pixel of the device 200 includes one single photodiode 2410 and one single microlens 251. Each of the microlenses 251 is configured to focus the incident light in the active layer 241, in an absorption region of the photodiode 2410 associated with the same pixel. The light is focused in a central area of said absorption area, to limit crosstalk related to the diffusion of carriers in the active layer.

The obvious solution for positioning the microlenses consists in placing these above the filtering stage, on the side opposite to the adhesive layer. The Inventors have had the idea of placing them rather between the filtering stage 210 and the adhesive layer 220. The arrangement of the microlenses under the filtering stage 210, between the filtering stage 210 and the adhesive layer 220, allows the focal length of the microlenses to be reduced, and not increase with the thickness of the filtering stage 210.

This feature is particularly useful herein, since the filtering stage should have a large thickness in order to be able to filter light in the infrared. Hence, an arrangement of the microlenses above the filtering stage would result in a very long focal length of these. Yet, a long focal length of the microlenses results in a large diameter of the Airy disk, which might generate crosstalk defects, and even render the microlenses useless, for example if the diameter of the Airy disk exceeds the distribution step of the photodiodes 2410. This crosstalk problem is related to the infrared context, in which the Airy disk diameters are much larger than in the visible. Crosstalk reduction is an even more serious problem when the active layer is made of an alloy of cadmium, mercury and tellurium, as this type of alloy could be more subject to electronic crosstalk.

In this case, the original arrangement of the microlenses therefore allows further improving colour rendering, while avoiding generating crosstalk because of an increase in the diameter of the Airy disk. This original arrangement of the microlenses also allows freely increasing a thickness of the filtering stage, for example to improve the quality of a spectral filtering implemented by the latter, with no negative consequences on the crosstalk.

The material of the microlenses 251 has a high refractive index. Consequently, their positioning between the filtering stage 210 and the adhesive layer 220 exacerbates optical signal modulations related to the variations in the thickness of the optical cavity described with reference to FIG. 1. Hence, the anti-reflective coating 230 described with reference to FIG. 1 herein finds additional interest.

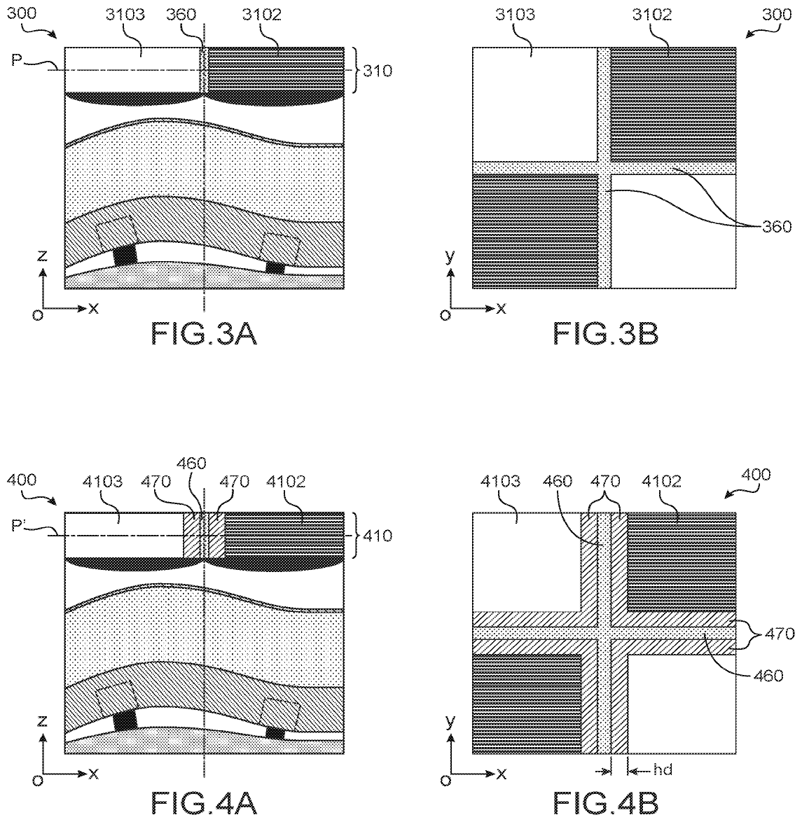

FIGS. 3A and 3B illustrate a device 300 according to a third embodiment, which will be described only for its differences with respect to the embodiment of FIG. 2. FIG. 3A is a sectional view in a vertical plane (Oxz). FIG. 3B is a sectional view in a horizontal plane P, parallel to the plane (Oxy) and passing through the filtering stage 310.

In the device 300, metal walls 360 extend between neighbouring filtering areas of the filtering stage 310, to separate filtering areas associated with distinct transmitted spectral bands. In this case, the metal walls 360 extend between pairs of two filtering areas, each including a filtering area 3102 of the first type and a filtering area 3103 of the second type.

The metal walls 360 are made of at least one metal, and preferably formed of copper. They form vertical structures, delimited by walls substantially orthogonal to the plane (Oxy). Preferably, these walls are inclined by less than 10°, with respect to the normal to the plane (Oxy).

Preferably, the metal walls 360 extend over the entire height, according to (Oz), of the filtering stage 310. They extend along lines defined in planes parallel to the plane (Oxy), herein straight lines. Their thickness is substantially constant along these lines. In this case, the metal walls 360 are in direct physical contact with each of the neighbouring filtering areas.

The metal walls 360 herein extend according to a series of straight lines which each extending from one edge to the other of the filtering area matrix. Together, they form a grid. In this case, there is one single filtering area 3102, 3103 in each hole of the grid. In variants that is not represented, it is possible to have several neighbouring filtering areas in each hole of the grid.

In this case, the metal walls 360 do not extend along the external edges of the filtering area matrix, so that the filtering areas located at the boundary of the matrix are surrounded by metal walls only on their edges located inside the matrix. According to an advantageous variant, not represented, the filtering stage may extend according to a slightly larger surface than the photodiode matrix in the active layer. Thus, the filtering areas located at the boundary of the matrix, and which are not entirely surrounded by metal walls, do not extend above a photodiode. Thus, there are “blind” pixels at the boundary of the matrix, but which represent only a small proportion of the total number of pixels in the device.

In a variant that is not represented, the walls also extend along the external edges of the filtering area matrix.

In use, an incident wave couples with planar waveguides formed by the alternation of high index and low index layers in a filtering area 3102. These guided modes, propagating in the high index layers of a filtering area, are generally absent from planar filters. They exist herein because of the presence of structures that diffract light, like for example the corners of the filtering areas, between neighbouring pixels. In the absence of the metal walls 360, light propagating in these planar waveguides may be captured by a neighbouring pixel. The metal walls 360 allow blocking the propagation of these guided modes. Thus, the metal walls 360 allow reducing a crosstalk, related to the propagation of modes from one filtering area to another of the filtering stage. In practice, the metal walls 360 allow reducing, in each pixel of the device 200, a spectral efficiency at wavelengths that are yet blocked by the filtering area associated with said pixel (amount of light detected by the photodiode, and then originating from a neighbouring pixel in which the filtering area allows these wavelengths to pass).

The modes TE and TM contribute to this crosstalk. In the case where the filtering area of the second type consists of a low index filler material, it is the guided modes TM which contribute the most to the crosstalk.

In this case, the metal walls 360 are bordered by pairs of two filtering areas, including a filtering area consisting of a stack of layers made of a dielectric material, and a filtering area consisting of a mere filler material. In a variant of the invention, the metal walls are bordered by pairs of two filtering areas, including a filtering area consisting of a first stack of layers made of a dielectric material, and a filtering area consisting of a second stack layers made of a dielectric material. Herein again, the metal walls allow reducing the crosstalk.

In other variants, the walls are not made of metal, but of an infrared-absorbing material (for example doped silicon)

FIGS. 4A and 4B illustrate a device 400 according to a fourth embodiment, which will be described only for its differences with respect to the embodiment of FIGS. 3A and 3B. FIG. 4A is a sectional view in a vertical plane (Oxz). FIG. 4B is a sectional view in a horizontal plane P′, parallel to the plane (Oxy) and passing through the filtering stage 410.

In this embodiment, the device 400 further includes intermediate partitions 470, made of a dielectric material. Each intermediate partition 470 forms a vertical structure, delimited by walls substantially orthogonal to the plane (Oxy) of the filtering stage 410. Preferably, the intermediate partitions 470 extend over the entire height, according (Oz), of the filtering stage 410. Each extends according to a line located in the plane (Oxy). Preferably, each intermediate partition 470 has a constant thickness along this line.

Each intermediate partition 470 herein in direct physical contact with a respective portion of a metal wall, and with an edge of a filtering area of the filtering matrix. Thus, it may be considered that an intermediate partition 470 covers at least one portion of a metal wall.

In this case, the metal walls 460 together define a grid, and intermediate partitions 470 cover each of the vertical facets of the grid, between a respective portion of a metal wall 460 and a respective edge of the filtering area 4102, 4103. Hence, each of the filtering areas 4102, 4103 is entirely surrounded by intermediate partitions 470, herein except for the filtering areas located at the boundary of the matrix which are surrounded only by intermediate partitions 470 on their edges located inside the matrix. In FIG. 4A, an matrix of only four pixels has been represented, so that all filtering areas are located at the matrix boundary, surrounded on only three sides.

According to an advantageous variant, not represented, the filtering stage may extend according to a slightly larger surface than the photodiode matrix in the active layer. Thus, the filtering areas located at the boundary of the matrix, and which are not entirely surrounded by metal walls and intermediate partitions, do not extend above a photodiode. Thus, there are “blind” pixels at the boundary of the matrix, but which represent only a small proportion of the total number of pixels in the device.

In a variant that is not represented, the walls also extend along the external edges of the filtering area matrix. In this case, each of the filtering areas 4102, 4103 is completely surrounded by intermediate partitions 470.

In another variant, the metal walls together define a grid, with several neighbouring filtering areas in each hole of the grid. Each intermediate partition then covers each of the vertical facets of the grid, along several neighbouring filtering areas.

In any case, each metal wall 460 portion located between two neighbouring filtering areas 4102, 4103, is herein bordered by a respective pair of two intermediate partitions 470. The structure formed by a metal wall 460 portion bordered between two intermediate partitions 470, is configured to modify the electromagnetic field at the exit from a so-called main filtering area, so as to reduce diffraction towards a neighbouring filtering area. The intermediate partitions 470 are intended in particular to reduce the angular aperture of diffracted light waves, emerging from a filtering area 4103 of the second type and propagating in a filtering area 4102 of the first type, where the filtering area 4103 of the second type consists of a mere filler material. It is about reducing more particularly the diffraction of the TM modes, contributing the most to the crosstalk. The role of the intermediate partitions 470 is to shift the field H away from the metal walls 460, which also results inter alia in a less dissipative loss. This improves the reduction of crosstalk. The electric field modification is effective at a cut-off wavelength, which delimits the second spectral band, transmitted by a filtering area 4103 of the second type, and the first spectral band, transmitted by a filtering area 41032 of the first type.

There is further a synergy effect between the intermediate partitions 470 and the microlenses located under the filtering stage. Indeed, the diameter of the Airy disk is reduced when the light reaches the microlenses in the form of a substantially planar wave (the wave being planarised by said reduction in diffraction towards a neighbouring filtering area).

It is possible to determine the conditions to be verified to obtain this field modification, using a parametric study. For this purpose, the parametric equation of the effective index of the fundamental mode TM in a so-called “MDD” structure, standing for Metal-Dielectric-Dielectric, consisting of a metal wall between two intermediate partitions, with on one side a filtering area of the first type and on the other side a filtering area of the second type herein consisting of a mere filler material. The parametric equation may depend on parameters such as the average dielectric permittivity in the filtering area of the second type, the dielectric permittivity of the metal wall, the dielectric permittivity of the intermediate partitions, and the thickness hd of the intermediate partitions, (defined in a plane (Oxy) parallel to the plane of the filtering area matrix). Afterwards, the values of the parameters for which the equation finds no solution are sought. This corresponds to the absence of the fundamental mode TMO, and therefore to the absence of the higher order modes TM. Of course, the modes TE remain. The parametric study is carried out for a determined wavelength, herein equal to the cut-off wavelength as mentioned hereinabove, delimiting the second spectral band, transmitted by a filtering area 4103 of the second type, and the first spectral band, transmitted by a filtering area 41032 of the first type.

The Inventors have demonstrated that the desired field modification is obtained more easily when a refractive index of the intermediate partitions is strictly lower than an average refractive index in the filtering area of the second type. It is also demonstrated that the desired field modification is obtained for a non-zero thickness hd, preferably strictly lower than a determined threshold value. Furthermore, it is demonstrated that the average dielectric permittivity in the filtering area of the second type is advantageously greater than or equal to 2, or greater than or equal to 3.

Such a parametric study is detailed hereinafter, associated with a structure consisting of a metal wall bordered by two intermediate partitions, with on one side a filtering area 4102 consisting of a stack of dielectric layers, and on the other side a filtering area 4103 consisting of a mere filler material. The parametric study allows determining the parameters allowing modifying the electromagnetic field at the output of the filtering area 4103 (consisting of a mere filler material), so as to reduce diffraction towards the filtering area 4102, in the range of wavelengths blocked by filtering area 4102 and transmitted by the filtering area 4103. The parametric study is based on an equation dependent on the effective index of the fundamental mode TM0, which is then the mode contributing the most to crosstalk. The parametric study is carried out for a cut-off wavelength equal to 4,000 nm. The effective index N meets the equation hereinbelow:

$${k}_{d} {h}_{d} = arctan ( \frac{{ε}_{d} {k}_{a}}{{ε}_{0} {k}_{d}} ) + arctan ( \frac{{ε}_{d} {k}_{m}}{{ε}_{m} {k}_{d}} ) \\ with {k}_{m} = {k}_{0} \sqrt{{N}^{2} - {ε}_{m}} , {k}_{d} = {k}_{0} \sqrt{{ε}_{d} - {N}^{2}} and {k}_{a} = {k}_{0} \sqrt{{N}^{2} - {ε}_{0}} \qquad ( 1 )$$

and with ε0 the dielectric permittivity of the filler material; εm the dielectric permittivity of the metal walls; εd the dielectric permittivity of the intermediate partitions; and hd the thickness of the intermediate partitions, considered in a plane (Oxy) parallel to the plane of the filtering area matrix.

The parametric study of equation (1) allows determining conditions in which there is no solution, i.e. conditions for which the fundamental mode TM0 does not exist in said structure. Thus, it is demonstrated for example that, for ε0=1, a guided mode TM0 exists for all thicknesses hd. On the other hand, for ε0=3, there is a threshold value of the thickness hd, below which no guided mode remains. For λ=4,000 nm, we have in particular

| hd (μm) | N |
|---|---|
| 1 | 1.79 |
| 0.95 | 1.79 |
| 0.8 | 1.79 |
| 0.7 | 1.8 |
| 0.6 | 0.18 |
| 0.5 | N/A |

Finally, for hd=0, the mode TM0 is found again. Hence, to impose a field H which is zero at the surface of the metal wall, the thickness of the intermediate partitions should herein be smaller than 500 nm and larger than 0 nm, for example comprised between 500 nm and 50 nm. Advantageously, this thickness hd is comprised between 80 nm and 150 nm, guaranteeing that the guided mode TM0 remains only for wavelengths much shorter than 3,000 nm. Furthermore, the refractive index nd in the intermediate partitions is advantageously strictly lower than the refractive index n0 of the filler material at the cut-off wavelength.

A similar parametric study may be implemented, when the structure including a metal wall between two intermediate partitions, extends between a filtering area consisting of a first stack of layers made of a dielectric material, and a filtering area consisting of a second stack of layers made of a dielectric material.

In a variant of the invention, the walls are not made of metal, but of an infrared-absorbing material (for example doped silicon).

For example, the evolution of the quantum efficiency QE of a pixel in a device according to the invention is described hereinafter. The encrypted data are obtained by simulation, and only takes optical crosstalk into consideration. The considered pixel includes a filtering area capable of blocking light in a spectral band B2, and to transmit the light in a spectral band B1. In one embodiment as illustrated in FIG. 1, the coefficient QE takes on the value 69 on the band B1, and the value 15 on the band B2. In a variant that differs only by the additional presence of microlenses, as illustrated in FIG. 2, the coefficient QE takes on the value 67 on the band B1, and the value 10 on the band B2. In a variant that differs only by the additional presence of metal walls, as illustrated in FIGS. 3A and 3B, the coefficient QE takes on the value 70 on the band B1, and the value 8 on the band B2. In a variant that differs only by the additional presence of intermediate partitions, as illustrated in FIGS. 4A and 4B, the coefficient QE takes on the value 85 on the band B1, and the value 7 on the band B2. Thus, an increasingly strong reduction in crosstalk is confirmed, through the addition of microlenses only at first, then of metal walls, then of intermediate partitions. As crosstalk decreases, the amount of light in the spectral band B1, passing into a neighbouring pixel, decreases. Hence, the quantum efficiency QE in the spectral band B1 increases accordingly. Similarly, as the crosstalk decreases, the amount of light in the spectral band B2, arriving from a neighbouring pixel whose filter transmits this spectral band B2, decreases. Hence, the quantum efficiency QE in the spectral band B2 decreases accordingly.

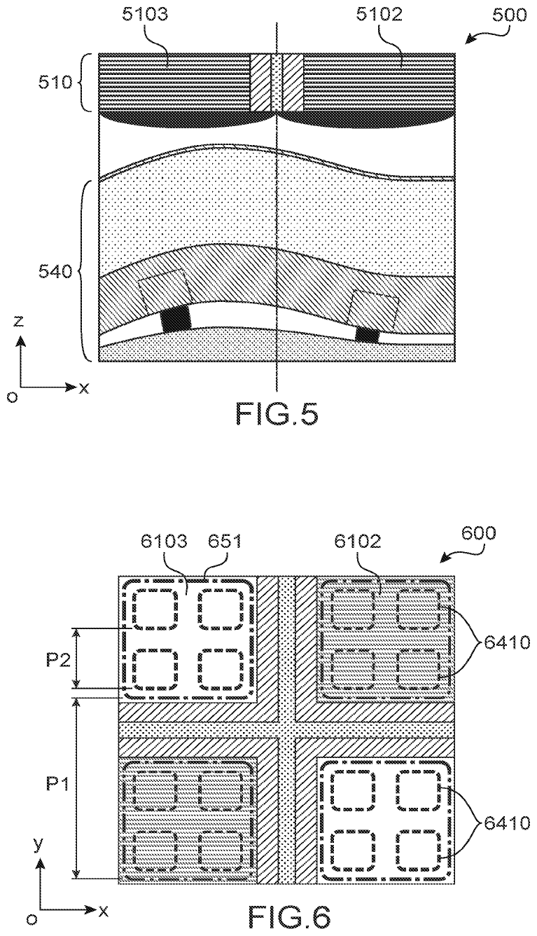

FIG. 5 schematically illustrates, according to a sectional view in a vertical plane (Oxz), a photo-detection device 500 according to a fifth embodiment of the invention.

This embodiment differs from that one of FIGS. 4A and 4B only in that, in the filtering stage 510, the filtering areas 5102 of the first type are capable of transmitting the wavelengths of a first spectral band and of blocking the wavelengths of a second spectral band, and the filtering areas 5103 of the second type are capable of transmitting the wavelengths of the second spectral band and of blocking the lengths of the first spectral band. The photodiodes integrated in the photo-detection stage 540 are sensitive both to the wavelengths of the first spectral band and to the wavelengths of the second spectral band. Each of the filtering areas of the first and second type then consists of a respective interference filter. Each of said interference filters consists of a stack of layers made of a dielectric material. Preferably, there is no layer that is common to the filtering areas of the first type and to the filtering areas of the second type.

Advantages similar to those of the embodiment of FIGS. 4A and 4B are found in this embodiment.

FIG. 6 schematically illustrates, in a sectional view in a horizontal plane (Oxy), a photo-detection device 600 according to a sixth embodiment of the invention.

In FIG. 6, the photodiodes 6410 integrated in the active layer and the microlenses 651 of the microlens matrix have been represented in transparency. The device 600 differs from the device of FIGS. 4A and 4B only in that a distribution step P1 of the microlenses 651 is a multiple of a distribution step P2 of the photodiodes 6410 (herein in each of the axes (Ox) and (Oy) of said matrices).

The filtering areas 6102, 6103 of the filtering area matrix are herein distributed according to the same distribution step as the microlenses, with one single filtering area above each microlens. In this case, metal walls bordered by intermediate partitions extend, according to a grid, between the filtering areas of the filtering area matrix.

Thus, it is possible to define, in the device 600, macro-pixels each including one single filtering area, one single microlens, and a plurality of photodiodes arranged in a sub-matrix. Each of the microlenses 651 is configured to focus the incident light, in the active layer, in a central region of the associated macro-pixel.

Thus, this embodiment allows reducing crosstalk between the macropixels. Indeed, in the active layer, the charge carriers may have a long lifetime and a long diffusion length (this is the case in particular in an active layer made of a cadmium, mercury, tellurium alloy). By focusing the light at the centre of the macro-pixel, it is ensured that the charge carriers are collected by a photodiode associated with the same macro-pixel, surmounted by the same filtering area as that at which the light arrived on the device 600. In other words, it is about increasing a pixel size, while rather considering macro-pixels, without modifying the photo-detection stage. This embodiment is particularly suitable when the active layer is N-doped, with P-doped regions each defining a photodiode. This embodiment is particularly suitable when the active layer is made of a cadmium, mercury, tellurium alloy, N-doped, with P-doped regions each defining a photodiode, or in any other configuration for which a diffusion length of the charge carriers in the active layer is in the range of 20 μm.

In this case, each macro-pixel includes a sub-matrix composed of four photodiodes distributed into two rows and two columns. Alternatively, each macro-pixel may include a sub-matrix composed of nine photodiodes distributed into three rows and three columns.

Preferably, the photo-detection device according to the invention is coupled to a cryogenic cooler, to lower the temperature of the photo-detection device to cryogenic temperatures, and thus to reduce the thermally induced noise to a level lower than that of the signal emitted by the scene.

Preferably, the device according to the invention has no microlenses located above the filtering stage, on the side opposite to the photo-detection stage. The only microlenses, when these exist, then extend only between the filtering stage and the photo-detection stage.

The invention is not limited to the above-described examples, and includes many other variants, with different materials and/or different dimensions and/or different wavelength ranges. Furthermore, the different embodiments described in the figures hereinabove may be combined. For example, the embodiment of FIG. 6 may be combined with that one of FIGS. 3A and 3B or with that one of FIG. 2 or FIG. 1. According to other variants, the anti-reflection layer is planar, and the photo-detection stage does not have any flatness defect. According to other variants, the metal walls may extend from one edge of the device to the other, according to discontinuous lines.

According to still other variants, the filtering area matrix may include filtering areas of at least three distinct types, to be able to discriminate the wavelengths of at least three distinct spectral bands. Each type of filtering area let the wavelengths of a specific transmitted spectral band pass. Each of the spectral bands transmitted covers a portion of a spectral sensitivity band of the photodiode matrix integrated in the active layer. Advantageously, the different transmitted spectral bands together cover the entirety of said spectral sensitivity band.

The invention also covers a system, not represented, comprising a photo-detection device according to the invention, and a cryogenic cooler thermally coupled to the latter. In use, the cryogenic cooler cools said device down to cryogenic temperatures, lower than or equal to 200 K, and even lower than or equal to 150 K, or lower than or equal to 120 K. A cryogenic cooler refers to a device capable of cooling an infrared detector to bring it down to cryogenic temperatures, and generally based on the use of a refrigerating gas.

A device according to the invention may be made through the following steps:
1/ depositing a first multilayer stack over an initial substrate made of silicon;
2/ local etchings of the first multilayer stack, to form a series of filters of the first type;
3/ depositing a filler material (or a second multilayer stack), filling the openings etched in step 2/, to form a series of filters of the second type;
4/ where appropriate, etching trenches between the filters of the first type and the filters of the second type, throughout an etching mask, and using a non-selective standard dry etching up to the substrate made of silicon;
5/ conformal deposition of a dielectric material over the etching edges of the trenches, to form the intermediate partitions, then standard deposition of metal at the centre of the trenches; or
5′/ filling the trenches by standard metal deposition.

Afterwards, the method may comprise a step of making the microlenses, for example using a resin mask. Afterwards, a first structure thus formed is transferred by bonding onto a second structure including the photo-detection stage provided with the anti-reflective coating. Afterwards, the initial substrate made of silicon is removed, for example by a so-called “fly-cutting” cut. Variants of this method may be implemented. However, the manufacturing method necessarily implements a transfer step by bonding, on a hybridised infrared detector (the photo-detection stage).

1. A device for multi-spectral photo-detection in the infrared, comprising:
a photo-detection stage and a filtering stage, superimposed on top of one another along an axis called the optical axis, wherein:
the photo-detection stage includes a read circuit, an active layer made of a semiconductor material and incorporating a matrix of photodiodes, and a support substrate, superimposed in that order along the optical axis, the read circuit being electrically connected to the photodiodes of the photodiode matrix;
the filtering stage comprises a matrix of filtering areas which consists of filtering areas of at least two types, including a first type each formed of an interference filter and each configured to transmit wavelengths of a first spectral band and to block wavelengths of a second spectral band, and a second type each configured to transmit at least part of the wavelengths of the second spectral band;
an adhesive layer which extends between the photo-detection stage and the filtering stage, with, in the photo-detection stage, the support substrate located on an adhesive layer side; and
an anti-reflective coating which extends between the adhesive layer and the support substrate, and which is configured to reduce inner reflections in the infrared.

2. The device according to claim 1, wherein a surface topology of the support substrate has a peak-valley amplitude greater than or equal to 3 μm at 300 K, on the adhesive layer side, and a surface topology of the filtering stage has a surface topology with a peak-valley amplitude less than or equal to 300 nm at 300 K, on the adhesive layer side, a difference between the two surface topologies being compensated by variations in thickness of the adhesive layer.

3. The device according to claim 1, further comprising a matrix of microlenses which extends between the adhesive layer and the filtering stage.

4. The device according to claim 3, wherein in at least one direction in space, a distribution step of the microlenses of the microlens matrix is a multiple of a distribution step of the photodiodes of the photodiode matrix.

5. The device according to claim 1, further comprising metal walls which extend into the filtering stage, between neighbouring filtering areas.

6. The device according to claim 5, wherein the metal walls extend together according to a grid, each opening of the grid comprising at least one filtering area of the filtering area matrix.

7. The device according to claim 6, wherein each opening of the grid includes a unique filtering area of the filtering area matrix.

8. The device according to claim 5, wherein at least one portion of at least one of the metal walls is bordered by two intermediate partitions made of a dielectric material.

9. The device according to claim 8, wherein a thickness of the intermediate partitions, defined in a plane orthogonal to the optical axis, is comprised between 500 nm and 50 nm.

10. The device according to claim 1, wherein each filtering area of the first type consists of a stack of layers each made of a dielectric material.

11. The device according to claim 10, wherein each filtering area of the second type is configured to transmit the wavelengths of the second spectral band and the wavelengths of the first spectral band, and consists of a dielectric filler material.

12. The device according to claim 10, wherein each filtering area of the second type is configured to transmit the wavelengths of the second spectral band and to block the wavelengths of the second spectral band, and consists of a respective interference filter.

13. The device according to claim 1, wherein the active layer is made of an alloy of cadmium, mercury and tellurium.

14. A system including a device according to claim 1, and a cryogenic cooler thermally coupled to the device, and configured to cool the device down to temperatures lower than or equal to 200 K.
